(19) United States
(12) Patent Application Publication
(10) Pub. No.: US 2026/0096069 A1
(43) Pub. Date: Apr. 2, 2026

(54) ELECTRONIC CONTROL DEVICE

(71) Applicant: HITACHI ASTEMO, LTD., Hitachinaka-shi, Ibaraki (JP)

(72) Inventors: Keiko UENO, Hitachinaka-shi, Ibaraki (JP); Yoshio KAWAI, Hitachinaka-shi, Ibaraki (JP); Tatsuya KANEKO, Hitachinaka-shi, Ibaraki (JP); Katsuyuki AONUMA, Hitachinaka-shi, Ibaraki (JP)

(73) Assignee: HITACHI ASTEMO, LTD., Hitachinaka-shi, Ibaraki (JP)

(21) Appl. No.: 19/113,095

(22) PCT Filed: Dec. 27, 2022
(86) PCT No.: PCT/JP2022/048427

§ 371 Date: Mar. 19, 2025

(51) Int. Cl. H05K 7/20

(52) U.S. Cl. CPC H05K 7/20854

(57) ABSTRACT

An electronic control device includes: a circuit board including a wiring board bearing a wiring pattern including a high-speed signal line, and an electronic component mounted on a first surface of the wiring board, the electronic component being connected to the high-speed signal line; a case housing the circuit board; and a first heat conductive member in direct contact with the electronic component and with the case. The first heat conductive member is disposed in such a way as to extend from an upper surface of the electronic component to the case and to extend from the first surface of the wiring board to the case while being in contact with a part of an outer peripheral surface of the electronic component at a position at which the first heat conductive member avoids a space above the high-speed signal line.

### TECHNICAL FIELD

The present invention relates to an electronic control device, more particularly, to an electronic control device in which a circuit board is housed in a case.

### BACKGROUND ART

In general, a vehicle, such as an automobile, has a plurality of electronic control devices incorporated therein. An electronic control device (which may hereinafter be referred to as an in-vehicle electronic control device) incorporated in a vehicle has a structure in which a circuit board bearing electronic components is housed in a case.

In recent years, enhancement of the functions of in-vehicle electronic control devices including an electronic control device for autonomous driving or an advanced driving assist systems has been in progress, leading to a trend in the increasing amount of heat generated by electronic components. If the temperature of an electronic component rises to a rated temperature or higher temperature to cause the electronic component a functional decline, it may invite an operation failure of the electronic control device. A method for suppressing a temperature rise of the electronic component caused by its heat generation is known. According to the method, heat generated by the electronic component is caused to escape to the case by using a thermal interface material (TIM), such as heat dissipating grease (see, for example, PTL 1.).

An electronic control device described in PTL 1 is configured such that a heat dissipating gel (TIM) filling a gap between a mounting surface of a substrate bearing a heat-generating electronic component (e.g., a power MOSFET as a semiconductor element) and a counter surface of a case, the counter surface being counter to the mounting surface, transfers heat generated by the electronic component to the case (see, for example, FIG. 18 of PLT 1). In other words, the heat dissipating gel is disposed in such a way as to completely cover the entire outer surface (an upper surface and the entire side surfaces) of the electronic component mounted on the substrate.

### CITATION LIST

### Patent Literature

PTL 1: JP 2011-023593 A

### SUMMARY OF INVENTION

### Technical Problem

In an electronic control device for autonomous driving or an advanced driving assist system, a heat-generating electronic component is provided, in some cases, as a high-functionality component that operates at a high speed, e.g., a system-on-chip (SoC) having a ball grid array (BGA) package structure. Such a high-functionality electronic component is electrically connected to a high-speed signal line in many cases. In the present specification, an electronic component that operates at an operation frequency higher than 100 MHz is defined as an electronic component capable of high-speed operation, and a signal line for transmitting a signal with a frequency higher than 100 MHz is defined as a high-speed signal line.

A case is assumed where the technique described in PTL 1 is applied to a high-functionality electronic component capable of high-speed operation to enhance its heat dissipation performance. In this case, the TIM is disposed in such a way as to cover the entire outer surface (the upper surface and the entire side surfaces) of the electronic component connected to the high-speed signal line on the substrate, thus giving rise to a concern of a decline in the quality of a radiofrequency signal transmitted through the high-speed signal line and an increase in radiation noise. This is because that disposing the TIM, which covers the electronic component, between the high-speed signal line on the substrate and the case creates a situation where a capacitance between the high-speed signal line and the case is increased by the TIM. This increase in the capacitance causes a drop in the quality of the radiofrequency signal and an increase in the radiation noise. A drop in the quality of the radiofrequency signal and an increase in the radiation noise give rise to a concern that the high functionality of the in-vehicle electronic control device drops.

According to the technique described in PTL 1, a power MOSFET is cited as a heat-generating electronic component mounted on the substrate. In general, the power MOSFET operates at a frequency lower than 100 MHz, which is assumed to be a frequency for high-speed operation defined in this description. This, therefore, gives less necessity of considering the above problem: a decline in the quality of the radiofrequency signal and an increase in the radiation noise that are caused by disposition of the TIM for enhancing the heat dissipation performance of the electronic component.

The present invention has been conceived to solve the above problem, and an object of the present invention is to provide an electronic control device that can ensure the quality of a radiofrequency signal and suppress radiation noise while maintaining heat dissipation performance.

### Solution to Problem

The present application includes a plurality of means for solving the above problem. As an example of the means for solving the above problem, an electronic control device comprises: a circuit board including a wiring board bearing a wiring pattern including a high-speed signal line, and an electronic component mounted on a first surface of both surfaces of the wiring board, the electronic component being electrically connected to the high-speed signal line; a case housing the circuit board; and a first heat conductive member in direct contact with the electronic component and with the case. The electronic component has a bottom surface facing the first surface of the wiring board, an upper surface located opposite to the bottom surface, and an outer peripheral surface connected to an outer edge of the bottom surface and to an outer edge of the upper surface. The first heat conductive member is disposed in such a way as to extend from the upper surface of the electronic component to the case and to extend from the first surface of the wiring board to the case while being in contact with a part of the outer peripheral surface of the electronic component at a position at which the first heat conductive member avoids a space above the high-speed signal line.

### Advantageous Effects of Invention

According to the present invention, by disposing the first heat conductive member in such a way as to put it in contact with the upper surface of the electronic component and with a part of the outer peripheral surface, heat dissipation performance is maintained, and by disposing the first heat conductive member at the position at which it avoids the high-speed signal line, an increase in the capacitance between the high-speed signal line and the case, which is caused by disposition of the first heat conductive member, can be avoided. Hence the quality of a radiofrequency signal is ensured and radiation noise is suppressed as heat dissipation performance is maintained.

Problems, configurations, and effects other than those described above will be made clear by the following description of embodiments.

### BRIEF DESCRIPTION OF DRAWINGS

FIG. 1 is a schematic perspective view of an electronic control device according to an embodiment of the present invention, showing the electronic control device in its disassembled state.

FIG. 2 is a schematic cross-sectional view of an electronic component of a circuit board and a peripheral structure around the electronic component in an electronic control device according to a first embodiment.

FIG. 3 is a schematic top view of the electronic component of the circuit board and the peripheral structure around the electronic component in the electronic control device according to the first embodiment.

FIG. 4 is a schematic perspective view of the electronic component of the circuit board and the peripheral structure around the electronic component in the electronic control device according to the first embodiment shown in FIG. 3.

FIG. 5 is a schematic top view of the electronic component of the circuit board and a peripheral structure around the electronic component in the electronic control device of a comparative example compared with the electronic control device according to the first embodiment.

FIG. 6 is a schematic cross-sectional view (a cross-section along the upper surface of the electronic component) showing disposition of a TIM in contact with side surfaces of the electronic component of a circuit board in an electronic control device according to a first modification of the first embodiment.

FIG. 7 is a schematic cross-sectional view (a cross-section along the upper surface of the electronic component) showing disposition of a TIM in contact with side surfaces of the electronic component of a circuit board in an electronic control device according to a second modification of the first embodiment.

FIG. 8 is a schematic cross-sectional view (a cross-section along the upper surface of the electronic component) showing disposition of a TIM in contact with a side surface of the electronic component of a circuit board in an electronic control device according to a third modification of the first embodiment.

FIG. 9 is a perspective view of the electronic component of a circuit board and a peripheral structure around the electronic component in an electronic control device according to a second embodiment of the present invention.

FIG. 10 is a schematic bottom view of the electronic component of a circuit board and the peripheral structure around the electronic component in the electronic control device according to the second embodiment.

FIG. 11 is a perspective view of the electronic component of a circuit board and a peripheral structure around the electronic component in an electronic control device according to a first example of a first modification of the second embodiment.

FIG. 12 is a perspective view of the electronic component of a circuit board and a peripheral structure around the electronic component in an electronic control device according to a second example of the first modification of the second embodiment.

FIG. 13 is a cross-sectional view of the electronic component of a circuit board and a peripheral structure around the electronic component in an electronic control device according to a first example of a second modification of the second embodiment.

FIG. 14 is a cross-sectional view of the electronic component of a circuit board and a peripheral structure around the electronic component in an electronic control device according to a second example of the second modification of the second embodiment.

FIG. 15 is a schematic diagram showing an arrangement relationship between the electronic component of the circuit board and heat conductive paths (through-holes) in an electronic control device according to a first example of a third modification of the second embodiment.

FIG. 16 is a schematic diagram showing an arrangement relationship between the electronic component of a circuit board and heat conductive paths (through-holes) in an electronic control device according to a second example of the third modification of the second embodiment.

FIG. 17 is a contour diagram showing a heat flow rate in the circuit board in the electronic control device according to the first example of the third modification of the second embodiment.

FIG. 18 is a schematic cross-sectional view of the electronic component of a circuit board and a peripheral structure around the electronic component in an electronic control device according to a third embodiment of the present invention.

FIG. 19 is a schematic perspective view of an appearance of an electronic control device according to a fourth embodiment of the present invention.

FIG. 20 is a schematic perspective view of an appearance of an electronic control device according to a fifth embodiment of the present invention.

### DESCRIPTION OF EMBODIMENTS

Embodiments of an electronic control device of present invention will hereinafter be described with reference to the drawings. In the present specification and drawings, constituent elements substantially identical in function or configuration are denoted by the identical reference signs to spare redundant description.

### First Embodiment

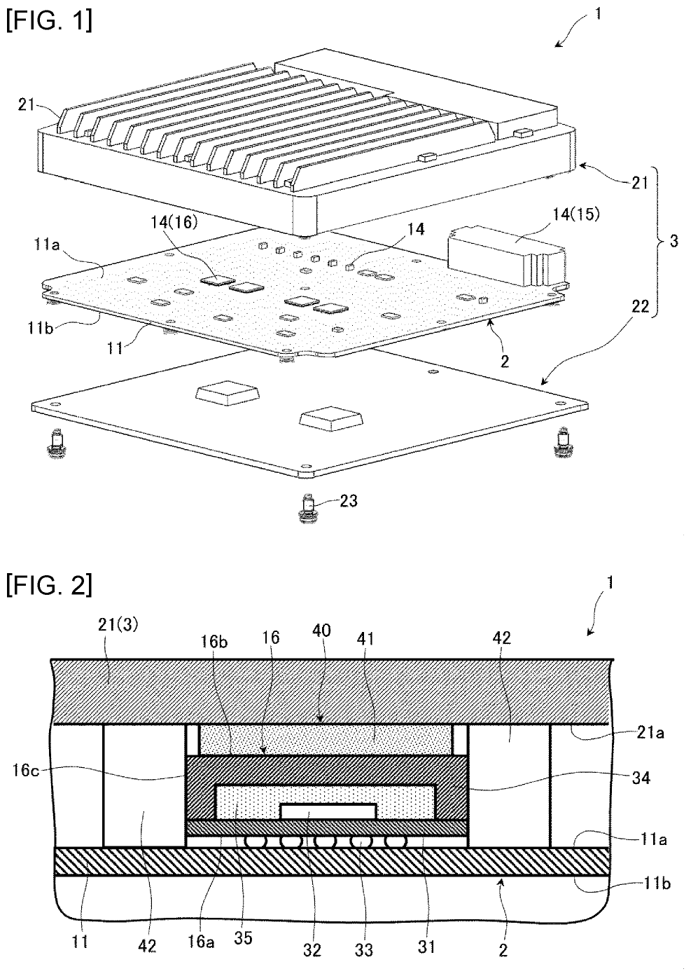

A configuration and a structure of an electronic control device according to a first embodiment will first be described with reference to FIG. 1. FIG. 1 is a schematic perspective view of the electronic control device according to the embodiment, showing the electronic control device in its disassembled state.

In FIG. 1, an electronic control device 1 according to this embodiment is a control device that performs high-speed communication. The electronic control device 1 is incorporated in, for example, a vehicle (not illustrated) and is used as a control device that controls or assists in driving the vehicle. The electronic control device 1 can be used also as a control device to control a millimeter wave radar, an in-vehicle camera, or the like. A control target of the electronic control device 1 is not limited to a specific object.

The electronic control device 1 includes a circuit board 2 making up an electronic circuit, and a case 3 hosing the circuit board 2.

The circuit board 2 includes a printed wiring board 11 bearing a wiring pattern (not shown) including a high-speed signal line 12, which will be described later (see FIG. 3 to be referred to later), and a plurality of electronic components 14 mounted on printed wiring board 11. The printed wiring board 11 has two surfaces, i.e., a first surface 11a and a second surface 11b, on which electronic components can be mounted. The printed wiring board 11 can be configured into either a single-sided board having a wiring pattern formed on only one of the first surface 11a and the second surface 11b or into a double-sided board having a wiring pattern formed on both of the same. The printed wiring board 11 is formed of, for example, a rigid board containing glass epoxy as a base material. The electronic components 14 include, for example, various elements, such as a resistance, a capacitor, a diode, a memory element, and a switching element, a connector 15, and a heat-generating electronic component 16 that requires a heat dissipation measure. In the circuit board 2 shown in FIG. 1, the heat-generating electronic component 16 is mounted on the first surface 11a of the printed wiring board 11. In other words, the first surface 11a of the printed wiring board 11 is the surface bearing the heat-generating electronic component 16.

The heat-generating electronic component 16 according to this embodiment is an electronic component capable of operating at a high-speed operation frequency ranging from several hundred MHz to several GHz. The electronic component 16 capable of high-speed operation (which will hereinafter be referred to as a “high-speed electronic component” in some cases) consumes a great amount of power when performing high-speed processing. Its power consumption may reach several tens of watts, and generate a lot of heat as a consequence. The high-speed electronic component 16 is, for example, a high-functionality component, such as a microcontroller with a built-in processor like a central processing unit (CPU) or a graphics processing unit (GPU), an integrated circuit (IC) chip, or a semiconductor chip. The electronic component 16 as a high-functionality component is capable of high-speed communication with various electronic components, such as a DDR memory and a SERializer having a signal conversion function. As another example of the high-speed electronic component 16, for example, a memory operating fast enough to allow high-speed communication with the above-mentioned microcontroller including the processor via a high-speed communication line is also considered to be the high-speed electronic component 16. The electronic component 16 operating at high speed generates a lot of heat and therefore requires a heat dissipation measure. A specific configuration of the high-speed electronic component 16 will be described later.

The case 3 includes, for example, a case body 21 forming an internal space that accommodates the circuit board 2, and a cover 22 that closes an opening of the case body 21, the opening allowing the circuit board 2 to be inserted in the case body 21. The case body 21 has a counter surface 21a (see FIG. 2 to be referred to later) counter to the first surface 11a (the surface bearing the electronic component 16) of the printed wiring board 11. The cover 22 is disposed counter to the second surface 11b of the printed wiring board 11. From the viewpoint of better heat dissipation performance, for example, the case body 21 and the cover 22 are formed of a metal material. The case body 21 having the circuit board 2 placed therein and the cover 22 are joined, using a plurality of screws 23.

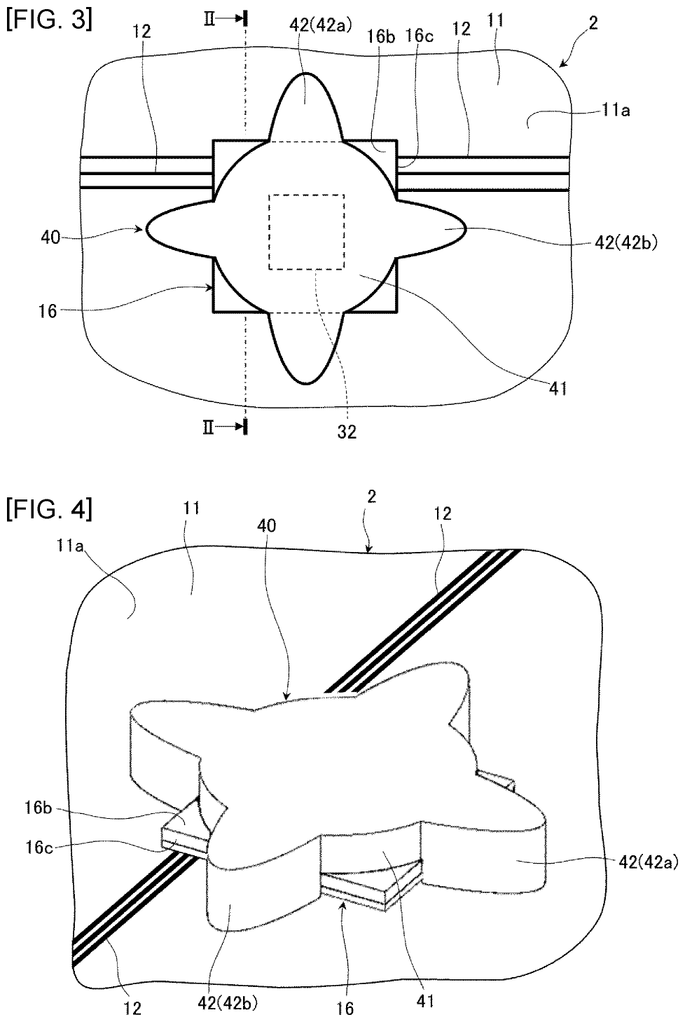

A configuration of the high-speed electronic component and a heat dissipation structure for the high-speed electronic component in the electronic control device according to the first embodiment will then be described with reference to FIGS. 2 to 4. FIG. 2 is a schematic cross-sectional view of the electronic component of the circuit board and a peripheral structure around the electronic component in the electronic control device according to the first embodiment. FIG. 3 is a schematic top view of the electronic component of the circuit board and the peripheral structure around the electronic component in the electronic control device according to the first embodiment. FIG. 4 is a schematic perspective view of the electronic component of the circuit board and the peripheral structure around the electronic component in the electronic control device according to the first embodiment shown in FIG. 3.

The electronic component 16 capable of high-speed operation is structured such that, for example, an IC chip 32 serving as a heat source is built in a semiconductor package of a ball grid array (BGA) structure, as shown in FIG. 2. More specifically, the electronic component 16 includes the IC chip 32 placed on a substrate 31, solder balls 33 that allow the IC chip 32 to electrically connect to a wiring pattern of the circuit board 2, a lid 34 covering the IC chip 32 to protect it, and a sealing resin 35 filling a space inside the lid 34 to seal the IC chip 32. The electronic component 16 is formed into a flat rectangular parallelepiped shape, which is a rectangular shape in a view from a side where an upper surface 16b is located, which will be described later. As shown in, for example, FIGS. 2 to 4, an outer surface of the high-speed electronic component 16 has a bottom surface 16a closer to the solder balls 33 facing the first surface 11a of the printed wiring board 11, an upper surface 16b located opposite to the bottom surface 16a, and an outer peripheral surface 16c connected to an outer edge of the bottom surface 16a and to an outer edge of the upper surface 16b. The upper surface 16b of the electronic component 16 is counter to the counter surface 21a of the case body 21 of the case 3. The outer peripheral surface 16c of the electronic component 16 is composed of four side surfaces.

As shown in FIGS. 3 and 4, the electronic component 16 capable of high-speed processing is connected to the high-speed signal line 12 (a part of the wiring pattern) on the printed wiring board 11. The high-speed signal line 12 is configured as a signal line capable of transmitting a radiofrequency signal of several hundred MHz to several GHz. The high-speed signal line 12 extends from, for example, two side surfaces 16c of four side surfaces 16c of the electronic component 16, the two side surfaces 16c being located opposite to each other. More specifically, the high-speed signal line 12 extends from an area on each side surface 16c, the area being close to a corner of the electronic component 16.

In the high-speed electronic component 16, the IC chip 32 generates heat because of its high-speed operation, which makes a heat dissipation measure necessary. For this reason, as shown in FIGS. 2 to 4, the outer surface of the high-speed electronic component 16 is thermally connected to the case body 21 of the case 3 via a heat conductive member 40. Specifically, the heat conductive member 40 is in direct contact with the electronic component 16 and the case body 21 and is therefore thermally connected to the electronic component 16 and the case body 21. The heat conductive member 40 thus has a function of transferring heat generated by the electronic component 16 to the case body 21. The heat conductive member 40 is made of a resin containing a heat conductive filler added thereto. As the heat conductive member 40, for example, a thermal interface material (TIM), such as heat dissipation grease or a heat conductive sheet made mainly of silicone, acrylic, epoxy, or urethane resin, is used.

As shown in FIGS. 3 and 4, the heat conductive member 40 of this embodiment is disposed in such a way as to be in contact with the upper surface 16b and a part of side surfaces 16c of the outer surface of the electronic component 16 at a position at which the heat conductive member 40 avoids a space above the high-speed signal line 12 of the printed wiring board 11. Specifically, the heat conductive member 40 has, for example, an upper surface conductive part 41 disposed in such a way as to extend from the upper surface 16b of the electronic component 16 to the counter surface 21a the case body 21, and four side surface conductive parts 42 each disposed in such a way as to extend from the printed wiring board 11 to the counter surface 21a of the case body 21 while being in contact with a central part (a part) of the corresponding side surface of four side surfaces 16c of the electronic component 16. The upper surface conductive part 41 is in contact with the upper surface 16b of the electronic component 16 in such a way as to include the entire area of an orthogonal projection of the IC chip 32 onto the upper surface 16b of the electronic component 16. In a view from a side where the upper surface 16b of the electronic component 16 is located, the side surface conductive parts 42 are composed of first side surface conductive parts 42a formed into substantially semi-elliptical shapes projecting respectively from central parts of two side surfaces 16c of the electronic component 16, the two side surfaces 16c not having the high-speed signal line 12 extending therefrom, and second side surface conductive parts 42b formed into substantially semi-elliptical shapes projecting respectively from central parts of the other two side surfaces 16c of the electronic component 16, the other two side surfaces 16c having the high-speed signal line 12 extending therefrom. Each second side surface conductive part 42b is disposed in such a way as to be in contact with the central part of the side surface 16c, the central part being a position at which the second side surface conductive part 42b avoids a space above the high-speed signal line 12, but not in contact with one end of the side surface 16c, the one end being on the high-speed signal line 12.

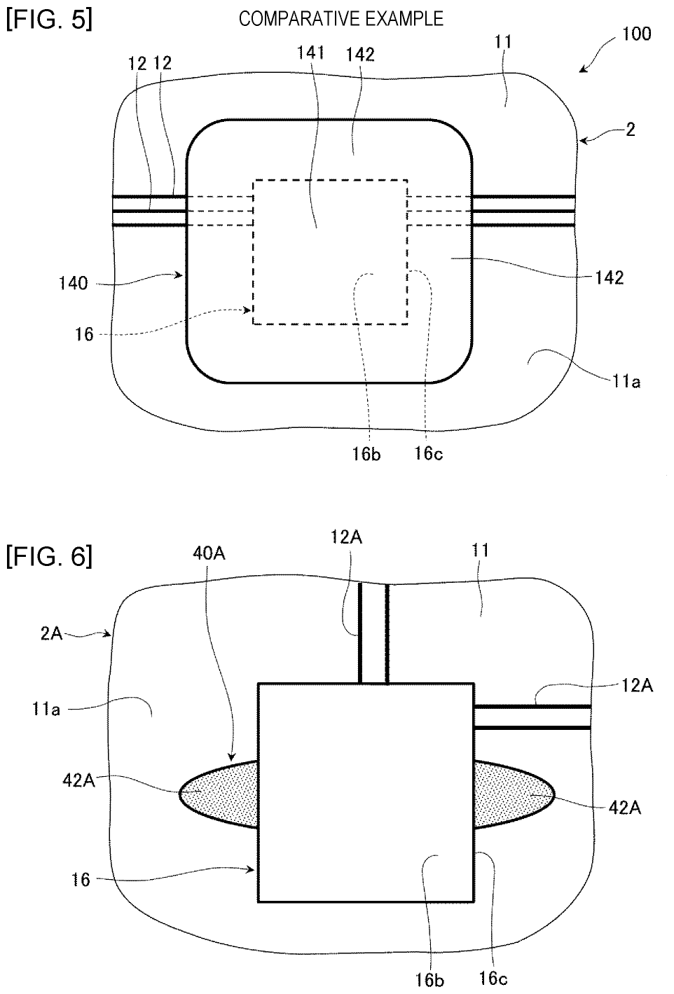

Effects of the heat conductive member in the electronic control device according to the first embodiment will then be described, using an electronic control device of a comparative example. First, a heat dissipation n structure of the electronic control device of the comparative example will be described with reference to FIG. 5. FIG. 5 is a schematic top view of the electronic component of the circuit board and a peripheral structure around the electronic component in the electronic control device of the comparative example compared with the electronic control device according to the first embodiment. In FIG. 5, components denoted by the same reference signs denoting components shown in FIGS. 1 to 4 are the same as the components shown in FIGS. 1 to 4, and therefore will not be described in detail in further description.

An electronic control device 100 of the comparative example shown in FIG. 5 is the same as the electronic control device 1 of this embodiment in the configuration and structure of the circuit board 2 and the case 3 but is different from the electronic control device 1 of this embodiment in the heat dissipation structure. Specifically, in the electronic control device 100 of the comparative example, the entire outer surface of the electronic component 16 mounted on the first surface 11a of the printed wiring board 11 of the circuit board 2 is thermally connected to the case body 21 (not shown in FIG. 5) of the case 3 via a heat conductive member 140. In other words, the heat conductive member 140 is in contact with the entire upper surface 16b and the entire four side surfaces 16c (the entire outer peripheral surface) of the electronic component 16. Specifically, the heat conductive member 140 has, for example, an upper surface conductive part 141 disposed in such a way as to extend from the upper surface 16b of the electronic component 16 to the counter surface 21a (not shown in FIG. 5) of the case body 21, and side surface conductive parts 142 disposed in such a way as to extend from the first surface 11a of the printed wiring board 11 to the counter surface 21a of the case body 21 while being in contact with the entire four side surfaces 16c of the electronic component 16. As a result, in the electronic control device 100 of the comparative example, a part of the side surface conductive parts 142 of the heat conductive member 140 is located in a space above the high-speed signal line 12 of the printed wiring board 11. The material of the heat conductive member 140 in the electronic control device 100 of the comparative example is the same as the material of the heat conductive member 40 in the electronic control device 1 of this embodiment.

Effects of the heat conductive member in the electronic control device according to the first embodiment will then be described with reference to FIGS. 2 to 5, based on effects the heat conductive member exert during operation of the electronic control device of the comparative example.

During operation of the electronic control device 100 of the comparative example shown in FIG. 5, the electronic component 16 performs high-speed communication with a different electronic component. When the electronic component 16 is a high-functionality component, for example, it performs high-speed communication with a memory through high-speed signal line 12 on printed wiring board 11. Performing such high-speed communication, various electronic components 14 mounted on the printed wiring board 11 (see FIG. 1) as well as the electronic component 16 generate heat, which causes the temperature of the electronic control device 100 of the comparative example to rise. At this time, heat of the electronic component 16 is transferred from the entire upper surface 16b of the electronic component 16 to the upper surface conductive part 141 of the heat conductive member 140 and is transferred from the entire four side surfaces 16c of the electronic component 16 to the side surface conductive parts 142 of the heat conductive member 140. Heat transferred to the upper surface conductive part 141 of the heat conductive member 140 and to the side surface conductive parts 142 of the heat conductive member 140 is released to outside of the case 3 through the case body 21 (see FIG. 1) of the case 3 and is transferred to the printed wiring board 11 as well. In the electronic control device 100 of the comparative example, because the heat conductive member 140 is disposed in such a way as to be in contact with the entire upper surface 16b and the entire four side surfaces 16c of the electronic component 16, a heat dissipation effect by the heat conductive member 140 can be enhanced.

However, in the electronic control device 100 of the comparative example, a part of the side surface conductive parts 142 of the heat conductive member 140 occupies the space above the high-speed signal line 12 of the printed wiring board 11. This disposition of the heat conductive member 140 increases a capacitance between the high-speed signal line 12 and the case body 21. A capacitance C is given by the following equation (1).

$$C = ε \cdot S / L \qquad equation ( 1 )$$

In Equation (1), ε denotes a relative permittivity, S represents the area of the high-speed signal line 12 in an area where the heat conductive member 140 is disposed, and L denotes a distance from the high-speed signal line 12 to the case body 21. The relative permittivity of air is 1, and the relative permittivity of the heat conductive member 140 is, for example, about 8. This means that the relative permittivity of the heat conductive member 140 is about 8 times that of air.

In this manner, in the electronic control device 100 of the comparative example, the capacitance between the high-speed signal line 12 of the printed wiring board 11 and the case body 21 increases because of the disposition of the heat conductive member 140. As a result, the quality of a radiofrequency signal transferred to the high-speed signal line 12 may drop and radiation noise may increase. If the quality of the radiofrequency signal drops or the radiation noise increases, it raises a concern that the high functionality of the electronic control device 100 drops.

In the electronic control device 1 according to this embodiment, however, the heat conductive member 40 is disposed in such a way as to extend from first surface 11a of the printed wiring board 11 to the case body 21 of the case 3 while being in contact with a part of outer peripheral surface 16c of the electronic component 16 at a position at which the heat conductive member 40 avoids the space above the high-speed signal line 12. As a result, the heat conductive member 40 is not disposed in an area between the high-speed signal line 12 and case body 21 and only the air is present in the area, in which case a capacitance in the area does not increase. It is therefore unnecessary to be concerned about a drop in the quality of the radiofrequency signal transferred through the high-speed signal line 12 and an increase in the radiation noise that results due to the disposition of the heat conductive member 40.

In addition, according to this embodiment, the heat conductive member 40 is disposed in such a way as to be in contact with the upper surface 16b of the electronic component 16 and with a part of each side surface of the four side surfaces 16c of the electronic component 16 as well. As a result, heat of the electronic component 16 is transferred from the upper surface 16b and the four side surfaces 16c to the heat conductive member 40, and therefore heat dissipation performance can be maintained.

In this embodiment, the heat conductive member 40 is disposed in such a way as to be in contact with a part of each side surface of the four side surfaces 16c of the electronic component 16. The heat conductive member 40 disposed in the above manner, compared with the heat conductive member 140 disposed in such a way as to be in contact with the entire four side surfaces 16c of the electronic component 16 in the electronic control device 100 of the comparative example, allows a reduction in an amount of use of the heat conductive member 40.

### Modifications of First Embodiment

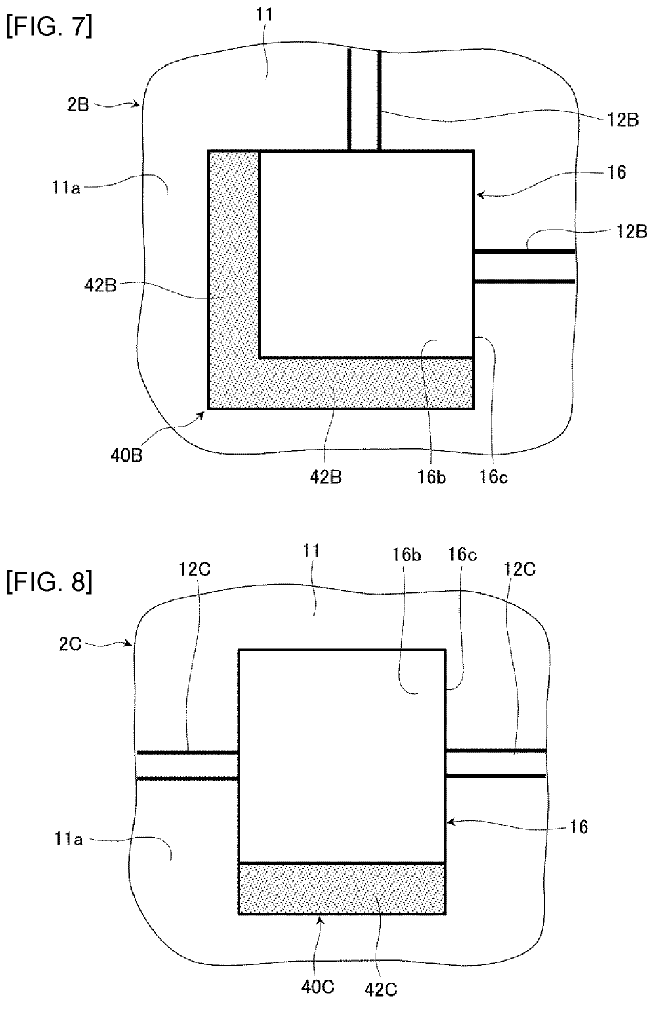

Electronic control devices according to modifications of the first embodiment will then be described with reference to FIGS. 6 to 8. FIG. 6 is a schematic cross-sectional view (a cross-section along the upper surface of the electronic component) showing disposition of a TIM in contact with side surfaces of the electronic component of a circuit board in an electronic control device according to a first modification of the first embodiment. FIG. 7 is a schematic cross-sectional view (a cross-section along the upper surface of the electronic component) showing disposition of a TIM in contact with side surfaces of the electronic component of a circuit board in an electronic control device according to a second modification of the first embodiment. FIG. 8 is a schematic cross-sectional view (a cross-section along the upper surface of the electronic component) showing disposition of a TIM in contact with a side surface of the electronic component of a circuit board in an electronic control device according to a third modification of the first embodiment.

The first modification of the first embodiment, the first modification being shown in FIG. 6, is different from the first embodiment in that disposition of a high-speed signal line 12A connected to the high-speed electronic component 16 on the printed wiring board 11 of a circuit board 2A is different from the disposition of the high-speed signal line of the first embodiment and that the structure of a heat conductive member 40A is different from the structure of the heat conductive member of the first embodiment. Specifically, the high-speed signal line 12A extends from two adjacent side surfaces 16c of the four side surfaces 16c of the electronic component 16. One part of the high-speed signal line 12A extends from the central part of one of the adjacent side surfaces 16c of the electronic component 16. The other part of the high-speed signal line 12A extends from the vicinity of a corner of the other one of the adjacent side surfaces 16c of the electronic component 16. In accordance with the disposition of the high-speed signal line 12A on the printed wiring board 11, the heat conductive member 40A is disposed in such a way as to extend from the first surface 11a of the printed wiring board 11 to the case body 21 of the case 3 while being in contact with a part of the outer peripheral surface 16c of the electronic component 16 at a position at which the heat conductive member 40A avoids the high-speed signal line 12A. Specifically, the heat conductive member 40A has the upper surface conductive part 41 (not shown), and side surface conductive parts 42A disposed in such a way as to extend from the first surface 11a of the printed wiring board 11 to the case body 21 of the case 3 while being in contact with respective central parts of side surfaces 16c located opposite to each other, the side surfaces 16c being included in the four side surfaces 16c of the electronic component 16. The heat conductive member is not disposed on a side surface 16c of electronic component 16 that has the high-speed signal line 12A extending from the central part of the side surface 16c.

The second modification of the first embodiment, the second modification being shown in FIG. 7, is different from the first embodiment in that the disposition of a high-speed signal line 12B connected to the high-speed electronic component 16 on the printed wiring board 11 of a circuit board 2B is different from the disposition of the high-speed signal line of the first embodiment and that the structure of a heat conductive member 40B is different from the structure of the heat conductive member of the first embodiment. Specifically, the high-speed signal line 12B extends from respective central parts of two adjacent side surfaces 16c of the four side surfaces 16c of the electronic component 16. In accordance with the disposition of the high-speed signal line 12B on the printed wiring board 11, the heat conductive member 40B is disposed in such a way as to extend from the first surface 11a of the printed wiring board 11 to the case body 21 of the case 3 while being in contact with a part of the outer peripheral surface 16c of the electronic component 16 at a position at which the heat conductive member 40B avoids the high-speed signal line 12B. Specifically, the heat conductive member 40B has the upper surface conductive part 41 (not shown), and side surface conductive parts 42B disposed in such a way as to extend from the first surface 11a of the printed wiring board 11 to the case body 21 of the case 3 while being in contact with the whole of two side surfaces 16c not having the high-speed signal line 12B extending therefrom and being adjacent to each other, the side surfaces 16c being included in the four side surfaces 16c of the electronic component 16. The heat conductive member is not disposed on side surfaces 16c of electronic component 16 that have the high-speed signal line 12A extending from the side surfaces 16c.

The third modification of the first embodiment, the third modification being shown in FIG. 8, is different from the first embodiment in that the disposition of a high-speed signal line 12C connected to the high-speed electronic component 16 on the printed wiring board 11 of a circuit board 2C is different from the disposition of the high-speed signal line of the first embodiment and that the structure of a heat conductive member 40C is different from the structure of the heat conductive member of the first embodiment. Specifically, the high-speed signal line 12C extends from respective central parts of two side surfaces 16c located opposite to each other, the two side surfaces 16c being included in the four side surfaces 16c of the electronic component 16. In accordance with the disposition of the high-speed signal line 12C on the printed wiring board 11, the heat conductive member 40C is disposed in such a way as to extend from the first surface 11a of the printed wiring board 11 to the case body 21 of the case 3 while being in contact with a part of the outer peripheral surface 16c of the electronic component 16 at a position at which the heat conductive member 40C avoids the high-speed signal line 12C. Specifically, the heat conductive member 40C has the upper surface conductive part 41 (not shown), and a side surface conductive part 42C disposed in such a way as to extend from the first surface 11a of the printed wiring board 11 to the case body 21 of the case 3 while being in contact with the whole of one side surface 16c not having the high-speed signal line 12B extending therefrom, the one side surface 16c being included in the four side surfaces 16c of the electronic component 16. The heat conductive member is not disposed on side surfaces 16c of electronic component 16 that have the high-speed signal line 12C extending from the side surfaces 16c.

In accordance with the disposition of each of the high-speed signal lines 12A, 12B, and 12C on the printed wiring board 11, each of the heat conductive members 40A, 40B, and 40C of the first, second, and third modifications is disposed in such a way as to extend from the first surface 11a of the printed wiring board 11 to the case body 21 of the case 3 while being in contact with a part of the outer peripheral surface 16c of the electronic component 16 at a position at which each of the heat conductive members 40A, 40B, and 40C avoids the space above the corresponding one of the high-speed signal line 12A, 12B, and 12C. It is therefore unnecessary, as in the case of the first embodiment, to be concerned about a drop in the quality of the radiofrequency signal transferred through each of the high-speed signal lines 12A, 12B, and 12C and an increase in the radiation noise that result due to the disposition of each of the heat conductive members 40A, 40B, and 40C.

In addition, the heat conductive member 40A of the first modification is disposed in such a way as to be in contact with the upper surface 16b of the electronic component 16 and with a part of each of two side surfaces of the four side surfaces 16c of the electronic component 16 as well. As a result, heat of the electronic component 16 is transferred from the upper surface 16b and the two side surfaces 16c, and therefore heat dissipation performance can be maintained. Because the heat conductive member 40A is disposed in such a way as to be in contact with a part of each of two side surfaces of the four side surfaces 16c of the electronic component 16, an amount of use of the heat conductive member 40A can be educed, compared with the case of using of the heat conductive member 40 in contact with a part of each side surface of the four side surfaces 16c of the electronic component 16 according to the first embodiment.

The heat conductive member 40B of the second modification is disposed in such a way as to be in contact with the upper surface 16b of the electronic component 16 and with the whole of two side surfaces of the four side surfaces 16c of the electronic component 16 as well. As a result, heat of the electronic component 16 is transferred from the upper surface 16b and the whole of the two side surfaces 16c, and therefore heat dissipation performance can be maintained.

The heat conductive member 40C of the third modification is disposed in such a way as to be in contact with the upper surface 16b of the electronic component 16 and with the whole of one side surface of the four side surfaces 16c of the electronic component 16 as well. As a result, heat of the electronic component 16 is transferred from the upper surface 16b and the whole of the one side surface 16c, and therefore heat dissipation performance can be maintained.

The electronic control device 1 of the first embodiment and modifications thereof include: circuit boards 2, 2A, 2B, and 2C having printed wiring boards 11 (wiring boards) bearing wiring patterns including high-speed signal lines 12, 12A, 12B, and 12C, and electronic components 16 mounted on first surfaces 11a of both surfaces of the printed wiring boards 11 (wiring boards), the electronic: components 16 being electrically connected to the high-speed signal lines 12, 12A, 12B, and 12C, respectively; cases 3 housing the circuit boards 2, 2A, 2B, and 2C, respectively; and heat conductive members 40, 40A, 40B, and 40C (first heat conductive members) in direct contact with the electronic components 16 and with the cases 3, respectively. The electronic component 16 has the bottom surface 16a facing the first surface 11a of the printed wiring board 11 (wiring board), the upper surface 16b located opposite to the bottom surface 16a, and the outer peripheral surface 16c connected to the outer edge of the bottom surface 16a and to the outer edge of the upper surface 16b. Each of the heat conductive members 40, 40A, 40B, and 40C (first heat conductive members) is disposed in such a way as to extend from the upper surface 16b of the electronic component 16 to the case 3 and to extend from the first surface 11a of the printed wiring board 11 (wiring board) to the case 3 while being in contact with a part of the outer peripheral surface 16c of the electronic component 16 at a position at which the heat conductive member avoids the corresponding one of the high-speed signal lines 12, 12A, 12B, and 12C.

According to this configuration, by disposing each of the heat conductive members 40, 40A, 40B, and 40C (first heat conductive members) in such a way as to put the heat conductive member in contact with the upper surface 16b of the electronic component 16 and with a part of the outer peripheral surface 16c, heat dissipation performance is maintained, and by disposing each of the heat conductive members 40, 40A, 40B, and 40C (first heat conductive members) at the position at which the heat conductive member avoids a space above the corresponding one of the high-speed signal lines 12, 12A, 12B, and 12C, an increase in the capacitance between each of the high-speed signal lines 12, 12A, 12B, and 12C and the case 3, which is caused by disposition of each of the heat conductive members 40, 40A, 40B, and 40C (first heat conductive members), can be avoided. Hence the quality of a radiofrequency signal is ensured and radiation noise is suppressed as heat dissipation performance is maintained.

The electronic component 16 of the electronic control device 1 according to the first embodiment is observed as a rectangular shape when seen from the side where the upper surface 16b is located, and has four side surface making up the outer peripheral surface 16c. The heat conductive member 40 (first heat conductive member) is disposed in such a way as to extend from the first surface 11a of the printed wiring board 11 (wiring board) to the case 3 while being in contact with a part of each side surface of the four side surfaces 16c of the electronic component 16 at the position at which the heat conductive member 40 avoids the space above the high-speed signal line 12.

According to this configuration, heat of the electronic component 16 is transferred from the upper surface 16b and each of the four side surfaces 16c to the heat conductive member 40 (first heat conductive member), and therefore, compared with a case where the heat conductive member 40 (first heat conductive member) is not contact with one of the four side surfaces 16c of the electronic component 16, heat dissipation performance can be improved.

In the electronic control device 1 according to the first embodiment, the electronic component includes the IC chip 32 (chip), which is a built-in heat source. The heat conductive member 40 (first heat conductive member) is in contact with the upper surface 16b of the electronic component 16 in such a way as to include the entire area of an orthogonal projection of the IC chip 32 (chip) onto the upper surface 16b of the electronic component 16.

In this configuration, the heat conductive member 40 (first heat conductive member) is brought into contact with an area of the upper surface 16b of the electronic component 16, the area coming to have a relatively high temperature due to heat from the IC chip 32 (chip) as the heat source. The heat dissipation performance of the heat conductive member 40 (first heat conductive member), therefore, can be improved.

### Second Embodiment

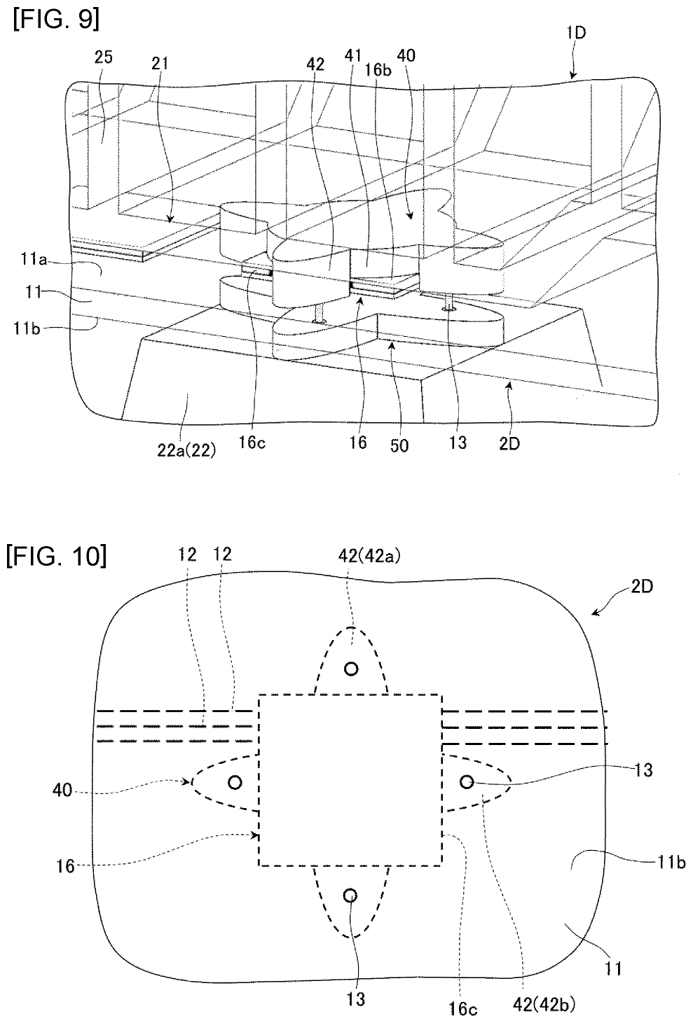

An electronic control device according to a second embodiment of the present invention will then be described with reference to FIGS. 9 and 10. FIG. 9 is a perspective view of the electronic component of a circuit board and a peripheral structure around the electronic component in the electronic control device according to the second embodiment of the present invention. FIG. 10 is a schematic bottom view of the electronic component of the circuit board and the peripheral structure around the electronic component in the electronic control device according to the second embodiment.

An electronic control device 1D according to the second embodiment shown in FIGS. 9 and 10 is different from the first embodiment mainly in that a heat conductive member 50 is disposed opposite to the heat conductive member 40 across the printed wiring board 11 of the circuit board 2D and that heat conductive paths 13 for thermally connecting the heat conductive member 50 to the heat conductive member 40 are provided on the printed wiring board 11 of the circuit board 2D. Other structural elements of the electronic control device 1D according to the second embodiment are the same as those of the electronic control device 1 according to the first embodiment, and therefore will be omitted in further description.

Specifically, the heat conductive paths 13 of the circuit board 2D are through-holes penetrating the printed wiring board 11 from its first surface 11a to second surface 11b, and have their inner surfaces overlaid with conductor plating. The heat conductive paths 13 are arranged at positions at which the heat conductive paths 13 can be thermally connected to the heat conductive member 40 on a case body 21 side, that is, disposed in areas where the side surface conductive parts 42 of the heat conductive member 40 are in contact with the first surface 11a of the printed wiring board 11. For example, four heat conductive paths 13 are arranged in such a way as to be thermally connected respectively to the side surface conductive parts 42 in contact with the side surfaces 16c of the electronic component 16.

The heat conductive member 50 is disposed in such a way as to extend from the second surface 11b of the printed wiring board 11 of the circuit board 2D to a protrusion 22a on the cover 22 of the case 3. The heat conductive member 50 on a cover 22 side is made of a resin containing a heat conductive filler added thereto, as the heat conductive member 40 on the case body 21 side is. As the heat conductive member 50, for example, a thermal interface material (TIM), such as heat dissipation grease or a heat conductive sheet, is used. The heat conductive member 50 on the cover 22 side is disposed in such a way as to be in direct contact with the heat conductive paths 13 of the circuit board 2D, and is configured to be thermally connected to the heat conductive member 40 on the case body 21 side via the heat conductive paths 13. For example, the heat conductive member 50 is formed such that the shape of an orthogonal projection of the heat conductive member 50 onto the printed wiring board 11 is substantially the same as the shape of an orthogonal projection of the heat conductive member 40 on the case body 21 side onto the printed wiring board 11. It should be noted, however, that the heat conductive member 50 may be of any given shape, providing that such a shape allows the heat conductive member 50 to be in direct contact with the heat conductive paths 13.

In this embodiment, the heat conductive member 40 in direct contact with the electronic component 16 and with the case body 21 of the case 3 is thermally connected to the heat conductive member 50 in direct contact with the cover 22 of the case 3 via the heat conductive paths 13 of the circuit board 2D. Thus, heat from the electronic component 16 is transferred to the case body 21 via the heat conductive member 40 and is released to outside of the case 3, and is transferred also from the heat conductive member 40 to the heat conductive member 50 through the heat conductive paths 13, is finally transferred to the cover 22, and is released to outside of the case 3. In other words, a heat dissipation path leading from the electronic component 16 to outside of the case 3 is provided not only on the case body 21 side but also on the cover 22 side. This allows heat dissipation from both sides, that is, from the case body 21 and the cover 22 of the case 3.

### First Modification of Second Embodiment

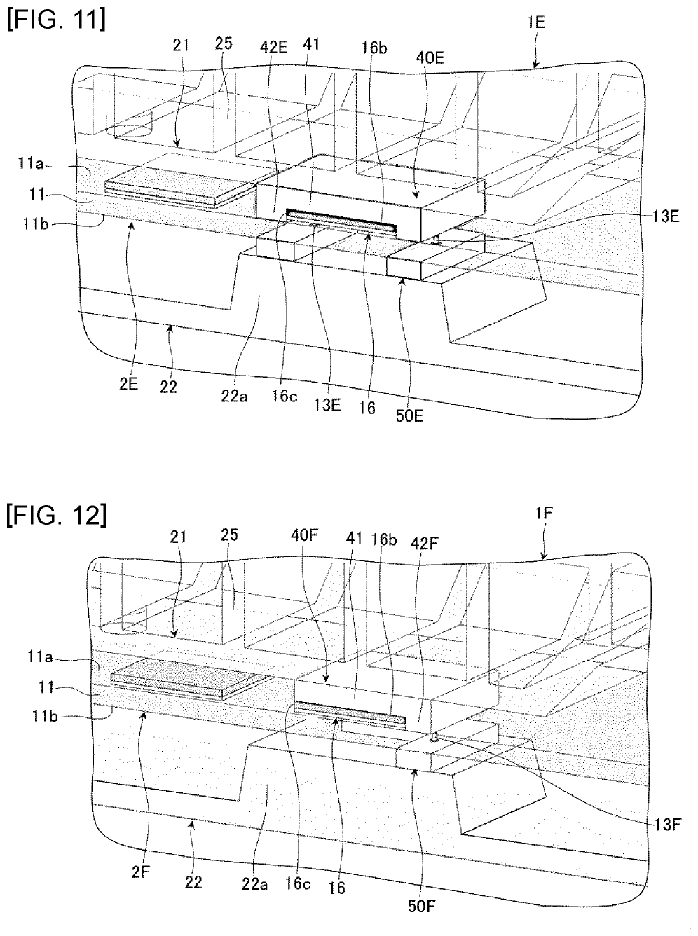

An electronic control device according to a first modification of the second embodiment will then be described with reference to FIGS. 11 and 12. FIG. 11 is a perspective view of the electronic component of a circuit board and a peripheral structure around the electronic component in the electronic control device according to a first example of the first modification of the second embodiment. FIG. 12 is a perspective view of the electronic component of a circuit board and a peripheral structure around the electronic component in an electronic control device according to a second example of the first modification of the second embodiment.

An electronic control device 1E according to the first example of the first modification of the second embodiment shown in FIG. 11 is different from the second embodiment mainly in the following respects. Firstly, a heat conductive member 40E on the case body 21 side is different in structure from the heat conductive member of the second embodiment. Secondly, the structure of a heat conductive member 50E on the cover 22 side is different from the structure of the heat conductive member on the cover 22 side of the second embodiment, in accordance with the structure of the heat conductive member 40E on the case body 21 side. Thirdly, arrangement of heat conductive paths 13E of a circuit board 2E is different from the arrangement of the heat conductive paths of the second embodiment in accordance with the structures of the heat conductive member 40E on the case body 21 side and the heat conductive member 50E on the cover 22 side.

Specifically, the heat conductive member 40E on the case body 21 side is disposed in such a way to be in contact with the upper surface 16b of the electronic component 16 and with the entire three side surfaces of the four side surfaces 16c. In other words, the heat conductive member 40E has the upper surface conductive part 41 in contact with the upper surface 16b of the electronic component 16, and three side surface conductive parts 42E in contact with the entire three side surfaces 16c of the electronic component 16. For example, three heat conductive paths 13E (of which two are shown In FIG. 11) are arranged in such a way as to be in contact with three side surface conductive parts 42E of the heat conductive member 40E, respectively. The heat conductive member 50E on the cover 22 side is disposed at a position at which the heat conductive member 50E is on the second surface 11b of the printed wiring board 11 in such a way as to avoid an area underneath the electronic component 16 and to include the position of arrangement of the heat conductive paths 13E. The for heat conductive member 50E is configured such that, example, the shape of an orthogonal projection of the heat conductive member 50E onto the printed wiring board 11 is the same as the shape of an orthogonal projection of three side surface conductive parts 42E of the heat conductive member 40E on the case body 21 side onto the printed wiring board 11.

An electronic control device 1F according to the second example of the first modification of the second embodiment shown in FIG. 12 is different from the second embodiment mainly in the following respects. First, a heat conductive member 40F on the case body 21 side is different in structure from the heat conductive member on the case body 21 side of the second embodiment. Secondly, the structure of a heat conductive member 50F on the cover 22 side is different from the structure of the heat conductive member on the cover 22 side of the second embodiment, in accordance with the structure of the heat conductive member 40F on the case body 21 side. Thirdly, arrangement of heat conductive paths 13F of a circuit board 2F is different from the arrangement of the heat conductive paths of the second embodiment in accordance with the structures of the heat conductive member 40F on the case body 21 side and the heat conductive member 50F on the cover 22 side.

Specifically, the heat conductive member 40F on the case body 21 side is disposed in such a way to be in contact with the upper surface 16b of the electronic component 16 and with the entire two adjacent side surfaces of the four side surfaces 16c. In other words, the heat conductive member 40F has the upper surface conductive part 41 in contact with the upper surface 16b of the electronic component 16, and two side surface conductive parts 42F in contact with the entire two adjacent side surfaces 16c of the electronic component 16. Two heat conductive paths 13F (of which one is shown In FIG. 12) are arranged in such a way as to be in contact with two side surface conductive parts 42F of the heat conductive member 40F, respectively. The heat conductive member 50F on the cover 22 side is disposed at a position at which the heat conductive member 50F is on the second surface 11b of the printed wiring board 11 in such a way as to avoid an area underneath the electronic component 16 and to include the position of arrangement of the heat conductive paths 13F. The heat conductive member 50F is configured such that, for example, the shape (L shape) of an orthogonal projection of the heat conductive member 50F onto the printed wiring board 11 is the same as the shape of an orthogonal projection of two side surface conductive parts 42F of the heat conductive member 40F on the case body 21 side onto the printed wiring board 11.

On the circuit boards 2E and 2F in the first and second examples of the first modification of the second embodiment, wiring lines and chip components may be densely mounted in an area of the second surface 11b of the printed wiring board 11, the area being the back of the part where the electronic component 16 with high functionality performance is mounted. This case imposes limitations on arrangement of the heat conductive members 50E and 50F on the cover 22 side. The heat conductive members 50E and 50F on the cover 22 side each have a structure for dealing with such an assumed case. The heat conductive members 50E and 50F are thermally connected to the heat conductive members 40E and 40F via the heat conductive paths 13E and 13F of the circuit boards 2E and 2F, respectively, thereby transferring heat from the electronic component 16 to the cover 22. It is therefore not necessary to dispose the heat conductive members 50E and 50F in such a way as to be in contact with the whole of the area of the second surface 11b of the printed wiring board 11, the area being the back of the part where the electronic component 16 is mounted.

In the first and second examples of the first modification, as in the case of the second embodiment, the heat conductive members 40E and 40F in direct contact with the electronic component 16 are thermally connected to the heat conductive members 50E and 50F via the heat conductive paths 13E and 13F of the circuit boards 2E and 2F, respectively. Thus, heat from the electronic component 16 is transferred to the case body 21 via the heat conductive members 40E and 40F and is released to outside of the case 3, and is transferred also from the heat conductive members 40E and 40F to the heat conductive members 50E and 50F through the heat conductive paths 13E and 13F, is finally transferred to the cover 22, and is released to outside of the case 3. In other words, a heat dissipation path leading from the electronic component 16 to outside of the case 3 is provided not only on the case body 21 side but also on the cover 22 side. This allows heat dissipation from both sides, that is, from the case body 21 and the cover 22 of the case 3.

### Second Modification of Second Embodiment

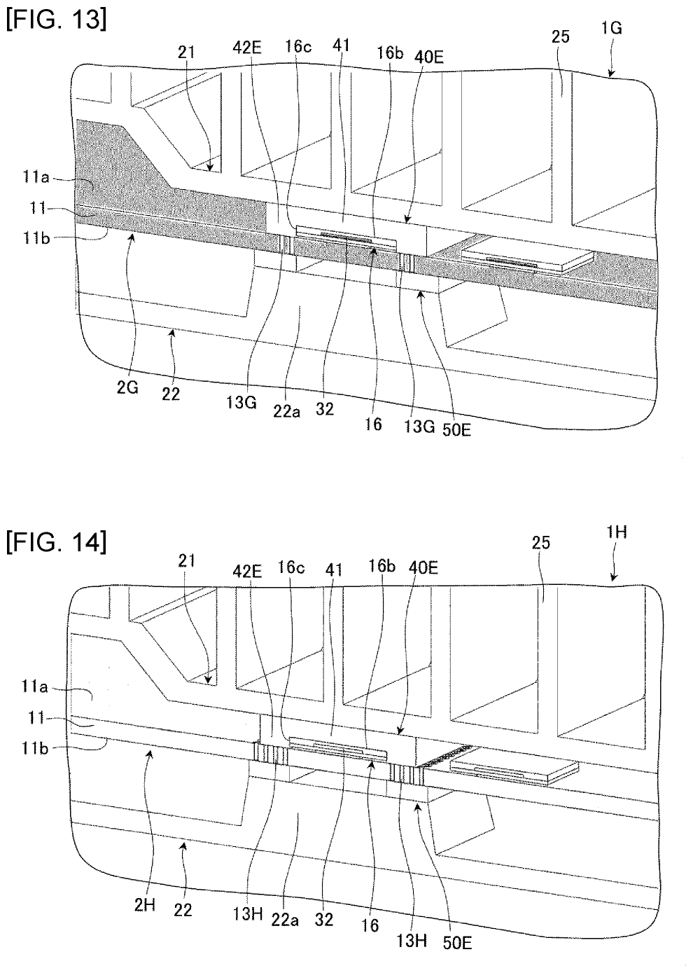

An electronic control device according to a second modification of the second embodiment will then be described with reference to FIGS. 13 and 14. FIG. 13 is a cross-sectional view of the electronic component of a circuit board and a peripheral structure around the electronic component in an electronic control device according to a first example of the second modification of the second embodiment. FIG. 14 is a cross-sectional view of the electronic component of a circuit board and a peripheral structure around the electronic component in an electronic control device according to a second example of the second modification of the second embodiment.

An electronic control device 1G according to the first example of the second modification of the second embodiment shown in FIG. 13 is different from the first example of the first modification of the second embodiment in that the arrangement and the number of heat conductive paths 13G of a circuit board 2G are different from the arrangement and the number of the heat conductive paths of the first example of the first modification of the second embodiment. Specifically, the heat conductive paths 13G are not arranged one by one on each of the three side surface conductive parts 42E of the heat conductive member 40E on the case body 21 side, but are arranged as rows of two heat conductive paths, each row being on each of the three side surface conductive parts 42E, that are spaced along the periphery direction of the side surface 16c of the electronic component 16.

An electronic control device 1H according to the second example of the second modification of the second embodiment shown in FIG. 14 is different from the first example of the second modification of the second embodiment in that the arrangement and the number of heat conductive paths 13H of the circuit board 2G are different from the arrangement and the number of the heat conductive paths of the second example of the second modification of the second embodiment. Specifically, the heat conductive paths 13H are arranged as rows of four heat conductive paths, each row being on each of the three side surface conductive parts 42E of the heat conductive member 40E on the case body 21 side, that are spaced along the periphery direction of the side surface 16c of the electronic component 16.

In the first and second examples of the second modification of the second embodiment, as in the case of the first example of the first modification of the second embodiment, the heat conductive members 40E in direct contact with the electronic component 16 are thermally connected to the heat conductive members 50E via the heat conductive paths 13G and 13H of the circuit boards 2G and 2H. Thus, heat from the electronic component 16 is transferred to the case body 21 via the heat conductive members 40E and is released to outside of the case 3, and is transferred also from the heat conductive members 40E to the heat conductive members 50E through the heat conductive paths 13G and 13H, is finally transferred to the cover 22, and is released to outside of the case 3. In other words, a heat dissipation path leading from the electronic component 16 to outside of the case 3 is provided not only on the case body 21 side but also on the cover 22 side. This allows heat dissipation from both sides, that is, from the case body 21 and the cover 22 of the case 3.

In addition, in the first and second examples of the second modification, the heat conductive paths 13G and 13H of the circuit boards 2G and 2H are arranged as rows of two heat conductive paths or four heat conductive paths (rows of multiple heat conductive paths) spaced along the side surfaces 16c of the electronic component 16, and are in contact with the heat conductive member 40 on the case body 21 side and with the heat conductive member 50E on the cover 22 side. According to this configuration, heat transfer from the heat conductive member 40E on the case body 21 side to the heat conductive member 50E on the cover 22 side via the heat conductive paths 13G and 13 H is carried out efficiently. As a result, the amount of heat transferred from the electronic component 16 to the heat conductive member 50E on the cover 22 side via the heat conductive paths 13G and 13H becomes larger than the same in the first example and the second example of the first modification of the second embodiment. This enhances heat dissipation performance.

### Third Modification of Second Embodiment

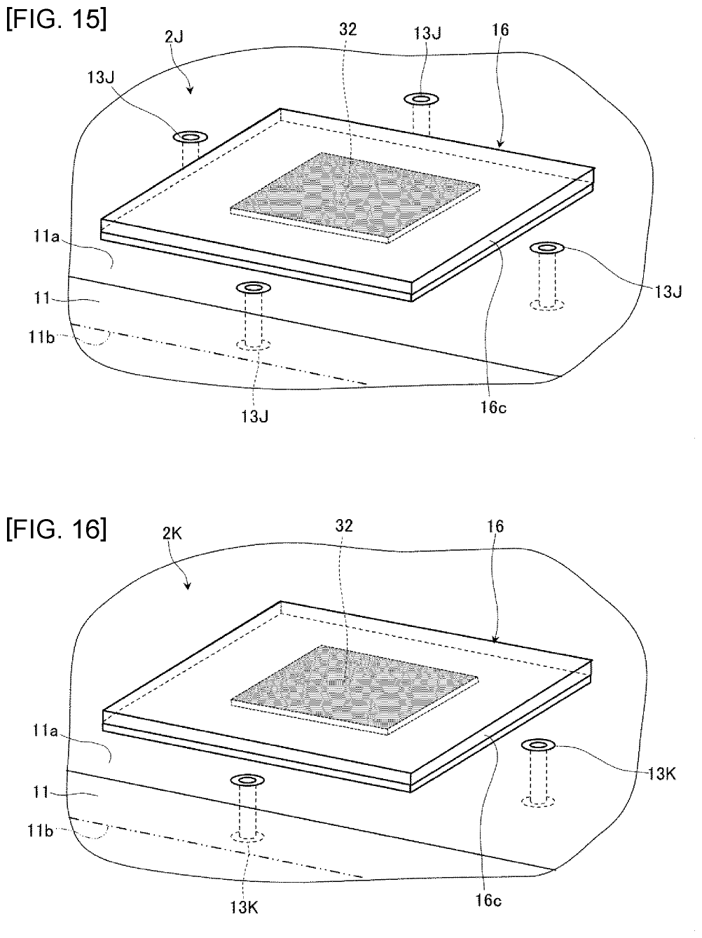

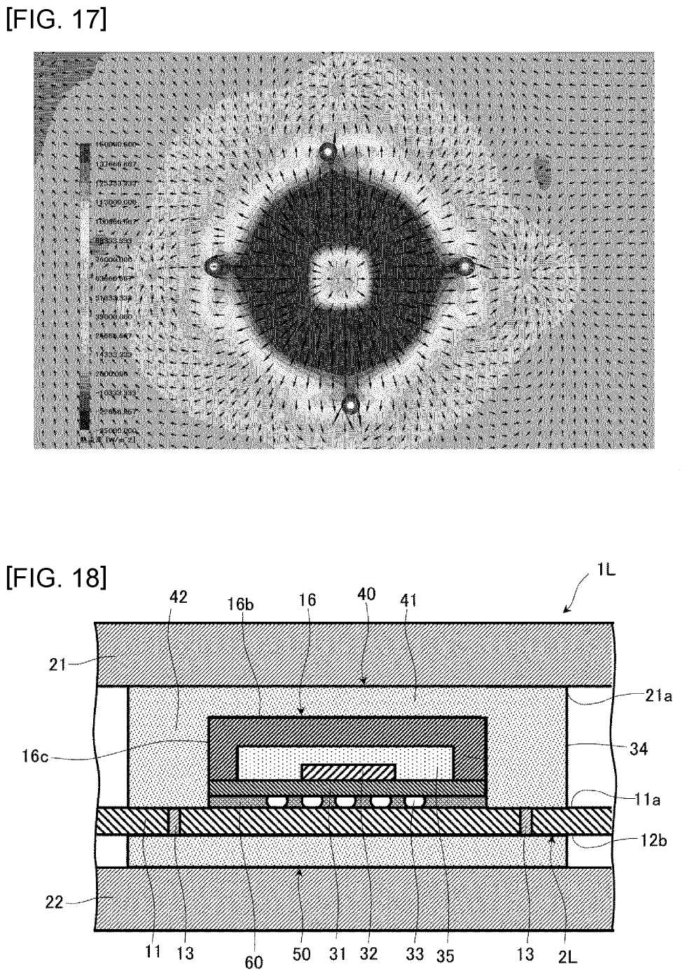

An electronic control device according to a third modification of the second embodiment will then be described with reference to FIGS. 15 to 17. FIG. 15 is a schematic diagram showing an arrangement relationship between the electronic component of a circuit board and heat conductive paths (through-holes) in an electronic control device according to a first example of the third modification of the second embodiment. FIG. 16 is a schematic diagram showing an arrangement relationship between the electronic component of a circuit board and heat conductive paths (through-holes) in an electronic control device according to a second example of the third modification of the second embodiment. FIG. 17 is a contour diagram showing a heat flow rate in the circuit board in the electronic control device according to the first example of the third modification of the second embodiment.

The electronic control device according to the first example of the third modification of the second embodiment shown in FIG. 15 is different from the second embodiment in that arrangement of heat conductive paths 13J of a circuit board 2J is different from the arrangement of the heat conductive paths in the second embodiment. Specifically, similarly to the heat conductive paths 13 of the circuit board 2D according to the second embodiment, heat conductive paths 13J of the circuit board 2J according to the first example of the third modification of the second embodiment are arranged in one-to-one correspondence to the central part of each side surface of the four side surfaces 16c of the electronic component 16, but each of the heat conductive paths 13J is located loser to the central part of each side surface of the four side surfaces 16c of the electronic component 16 than each of the heat conductive paths 13 according to the second embodiment.

The electronic control device according to the second example of the third modification of the second embodiment shown in FIG. 16 is different from the first example of the third modification of the second embodiment in that arrangement of heat conductive paths 13K of a circuit board 2K is different from the arrangement of the heat conductive paths of the first example of the third modification of the second embodiment. Specifically, the heat conductive paths 13K of the circuit board 2K according to the second example of the third modification of the second embodiment, the heat conductive paths 13K being different in arrangement from the heat conductive paths 13J according to the first example of the third modification of the second embodiment, are arranged in one-to-one correspondence to each of two adjacent side surfaces of the four side surfaces 16c of the electronic component 16 and are each located closer to the central part of each of two side surfaces 16c of the electronic component 16 in the same manner as the heat conductive paths 13J according to the second example of the third modification.

In the electronic control device according to the first and second examples of the third modification of the second embodiment, the heat conductive paths 13J and 13K of the circuit boards 2J and 2K are disposed at positions at which the heat conductive paths 13J and 13K correspond to the central part of at least one of the four side surfaces 16c of the electronic component 16. As it can be seen from a thermal fluid analysis result shown in FIG. 17, heat from the IC chip 32 at the center of the electronic component 16 is transferred radially. For this reason, heat from the IC chip 32 is transferred most intensively to the central part of each side surface 16c of the electronic component 16. Therefore, through the heat conductive paths 13J and 13K of the circuit boards 2J and 2K, heat can be transferred efficiently from the heat conductive member (not shown) on the case body 21 side to the heat conductive member (not shown) on the cover 22 side.

In the first and the second examples of the third modification of the second embodiment, the electronic component 16 has the IC chip 32 serving as the heat source at its center, and a plurality of the heat conductive paths 13J and 13K of the circuit boards 2J and 2K are spaced at the positions equal in distance to the IC chip 32 serving as the heat source of the electronic component 16.

According to this configuration, because of radial transfer of heat from the IC chip 32 as the heat source, substantially the same amount of heat is transferred to the plurality of heat conductive paths 13J and 13K located at the positions equal in distance to the IC chip 32. This allows heat dissipation with no partiality.

In the first and second examples of the third modification of the second embodiment, it is preferable that the heat conductive paths 13J and 13K of the circuit boards 2J and 2K be disposed at positions at which the heat conductive paths 13J and 13K are closest to the outer peripheral surface 16c of the electronic component 16. According to this configuration, heat radially transferred from the electronic component 16 can be led efficiently to the heat conductive paths 13J and 13K.

As described above, according to the second embodiment and the modifications thereof, by disposing each of the heat conductive members 40, 40E, and 40F (first heat conductive members) in such a way as to put the heat conductive member in contact with the upper surface 16b of the electronic component 16 and with a part of the outer peripheral surface 16c, heat dissipation performance is maintained, and by disposing each of the heat conductive members 40, 40E, and 40F (first heat conductive members) at the position at which the heat conductive member avoids a space above the high-speed signal line 12, an increase in the capacitance between the high-speed signal line 12 and the case 3, which is caused by arrangement of each of the heat conductive members 40, 40E, and 40F (first heat conductive members), can be avoided, in the same manner as in the first embodiment. Hence the quality of a radiofrequency signal is ensured and radiation noise is suppressed as heat dissipation performance is maintained.

In this embodiment and the modifications thereof, the circuit boards 2D, 2E, 2F, 2G, 2H, 2J, and 2K have the heat conductive paths 13, 13E, 13 F, 13G, 13H, 13J, and 13K provided on the printed wiring board 11 (wiring board), respectively, and the heat conductive paths 13, 13E, 13F, 13G, 13H, 13J, and 13K of circuit boards 2D, 2E, 2F, 2G, 2H, 2J, and 2K are disposed at the positions at which the heat conductive paths 13, 13E, 13F, 13G, 13H, 13J, and 13K can be thermally connectable to the heat conductive members 40, 40E, and 40F (first heat conductive members).

According to this configuration, heat of the electronic component 16 is transferred from the heat conductive members 40, 40E, and 40F (first heat conductive members) to the case 3, and is transferred also from the heat conductive members 40, 40E, and 40F (first heat conductive members) to the printed wiring boards 11 (wiring boards) of the circuit boards 2D, 2E, 2F, 2G, 2H, 2J, and 2K via the heat conductive paths 13, 13E, 13 F, 13G, 13H, 13J, and 13K of the circuit boards 2D, 2E, 2F, 2G, 2H, 2J, and 2K. This configuration, therefore, improves heat dissipation performance more greatly than the first embodiment and the modification thereof.

The electronic control device according to this embodiment and the modifications thereof further include the heat conductive members 50, 50E, and 50 F (second heat conductive members) each of which is in direct contact with the second surface 11b located on the back of the first surface 11a of both surfaces of the printed wiring board 11 (wiring board) and with the case 3. The heat conductive members 50, 50E, and 50F (second heat conductive members) are thermally connected to the heat conductive members 40, 40E, and 40F (first heat conductive members) via the heat conductive paths 13, 13E, 13F, 13G, 13H, 13J, and 13K of the circuit boards 2D, 2E, 2F, 2G, 2H, 2J, and 2K.

According to this configuration, heat of the electronic component 16 is transferred to one side (case body 21) of the case 3 via the heat conductive members 40, 40E, and 40F (first heat conductive members) and is released to outside, and is transferred also to the heat conductive members 50, 50E, and 50F (second heat conductive members) via the heat conductive paths 13, 13E, 13F, 13G, 13H, 13J, and 13K, is finally transferred to the other side (cover 22) of the case 3, and is released to outside. In other words, two kinds of heat dissipation paths leading from the electronic component 16 to outside of the case 3 are provided, as a heat dissipation path on one side of the case 3 and a heat dissipation path on the other side of the case 3. Hence heat dissipation performance can be enhanced.

In the second embodiment, the heat conductive member 40 (first heat conductive member) is disposed in such a way as to be in contact with a part of each side surface of the four side surfaces 16c of the electronic component 16 at the position at which the heat conductive member 40 avoids a space above the high-speed signal line 12, and the heat conductive paths 13 of the circuit board 2D are arranged in on-to-one correspondence to each of the four side surfaces 16c of the electronic component 16.

According to this configuration, heat of the electronic component 16 is transferred to the heat conductive paths 13 arranged in one-to-one correspondence to the four side surfaces 16c of the electronic component 16 via the heat conductive member 40 (first heat conductive member) in contact with the four side surfaces 16c of the electronic component 16. Thus, heat transfer from the electronic component 16 to the heat conductive paths 13 can be carried out efficiently and therefore heat dissipation performance is improved.

### Third Embodiment

An electronic control device according to a third embodiment of the present invention will then be described with reference to FIG. 18. FIG. 18 is a schematic cross-sectional view of the electronic component of a circuit board and a peripheral structure around the electronic component in an electronic control device according to the third embodiment of the present invention.

An electronic control device 1L according to the third embodiment shown in FIG. 18 is different from the second embodiment in that the electronic control device 1L further includes a heat conductive member 60 interposed between the first surface 11a of the printed wiring board 11 and the bottom surface 16a of the electronic component 16. Specifically, the heat conductive member 60 is an underfill that reinforces a solder joint between solder balls 33 on the bottom surface 16a of the electronic component 16 and a wiring pattern on the first surface 11a of printed wiring board 11. The underfill 60, which improves the life of the solder joint, is made of, for example, an epoxy resin and functions as a heat conductive member. Other structural elements of the electronic control device 1L according to the third embodiment are the same as those of the electronic control device 1D according to the second embodiment, and are therefore will be omitted in further description.

In this embodiment, in addition to the heat conductive member 40 on the case body 21 side and the heat conductive member 50 on the cover 22 side, the underfill 60 interposed between the printed wiring board 11 and the electronic component 16 in the circuit board 2L functions as the heat conductive member for transferring heat of the electronic component 16. This makes it possible to increase an amount of heat transfer from the electronic component 16 to the printed wiring board 11 while improving the reliability of the solder joint between the electronic component 16 and the printed wiring board 11. Thus, an improvement in solder life and an improvement in heat dissipation performance can be achieved simultaneously.

According to the third embodiment, by disposing the heat conductive member 40 (first heat conductive member) in such a way as to put the heat conductive member 40 in contact with the upper surface 16b of the electronic component 16 and with a part of the outer peripheral surface 16c, heat dissipation performance is maintained, and by disposing the heat conductive members 40 (first heat conductive member) at the position at which the heat conductive member 40 avoids a space above the high-speed signal line (not shown), an increase in the capacitance between the high-speed signal line and the case 3, which is caused by arrangement of the heat conductive member 40 (first heat conductive member), can be avoided, in the same manner as in the first embodiment, in the same manner as in the first embodiment. Hence the quality of a radiofrequency signal is ensured and radiation noise is suppressed as heat dissipation performance is maintained.

The electronic control device 1L according to the third embodiment further includes the heat conductive member 60 interposed between the first surface 11a of the printed wiring board 11 (wiring board) and the bottom surface 16a of the electronic component 16.

According to this configuration, heat of the electronic component 16 can be transferred to the case 3 via the heat conductive member 40 and can also be transferred to the printed wiring board 11 (wiring board) via the heat conductive member 60. Hence heat dissipation performance can be improved.

In this embodiment, the heat conductive member 60 (third heat conductive member) is the underfill that reinforces the solder joint on the bottom surface 16a of the electronic component 16.

According to this configuration, the heat conductive member 60 allows an improvement in both solder life and heat dissipation performance.

### Fourth Embodiment

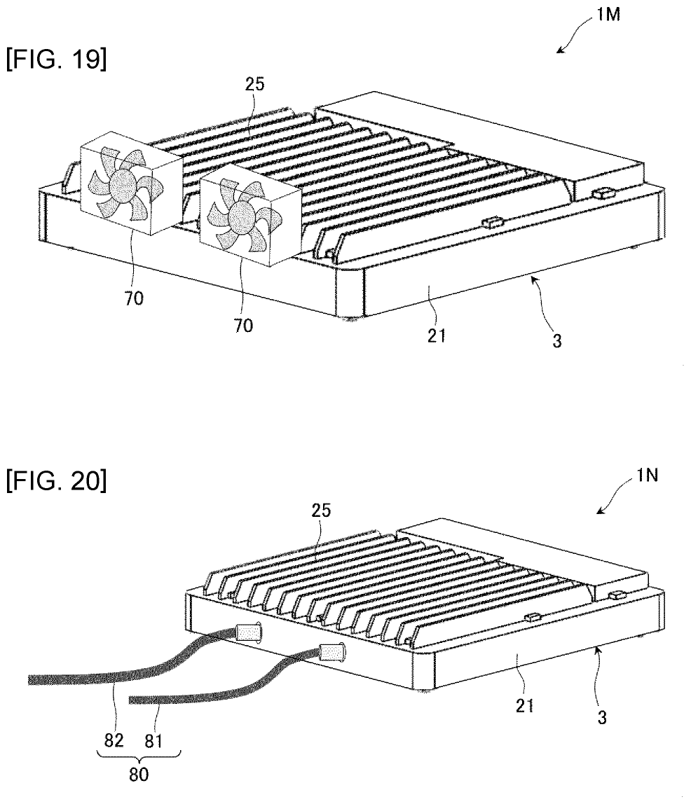

An electronic control device according to a fourth embodiment of the present invention will then be described with reference to FIG. 19. FIG. 19 is a schematic perspective view of an appearance of the electronic control device according to the fourth embodiment of the present invention. In FIG. 19, components denoted by the same reference signs denoting components shown in FIGS. 1 to 18 are the same as the components shown in FIGS. 1 to 18, and therefore will not be described in detail in further description.

An electronic control device 1M according to the fourth embodiment shown in FIG. 19 is different from the first embodiment in that cooling fans 70 are attached to the case body 21 of the case 3. The electronic control device 1M is a device of a forced air cooling type that supplies cooling air generated by the cooling fans 70 to a heat dissipation fin 25 of the case body 21.

In this embodiment, cooling air generated by the cooling fans 70 shown in FIG. 19 drives out heat, which is transferred from the electronic component 16 shown in FIG. 2 to the case body 21 of the case 3 via the heat conductive member 40. This causes the temperature of the case 3 to drop to increase a temperature difference between the case 3 and the electronic component 16, which accelerates heat transfer from the electronic component 16 to the case 3. Thus, the heat dissipation performance of the electronic control device 1M is further improved.

As described above, the electronic control device 1M according to this embodiment further includes the cooling fans 70 that supply cooling air to the outer surface of the case 3. According to this configuration, heat transfer from the electronic component 16 to the case 3 is accelerated and therefore the heat dissipation performance of the electronic control device 1M is further improved.

### Fifth Embodiment

An electronic control device according to a fifth embodiment of the present invention will be described with reference to FIG. 20. FIG. 20 is a schematic perspective view of an appearance of the electronic control device according to the fifth embodiment of the present invention. In FIG. 20, components denoted by the same reference signs denoting components shown in FIGS. 1 to 19 are the same as the components shown in FIGS. 1 to 19, and therefore will not be described in detail in further description.

An electronic control device IN according to the fifth embodiment shown in FIG. 20 is different from the first embodiment in that the electronic control device IN is provided with a water-cooling system 80 that supplies cooling water to the case 3 to cool the case 3. Specifically, the water-cooling system 80 includes a supply line 81 that supplies cooling water to the case 3, and a discharge line 82 through which cooling water discharged from the case 3 flows. The electronic control device 1 is a device of a forced water-cooling type that cools the case 3 by cooling water supplied through the supply line 81 and then discharges cooling water through the discharge line 82.

In this embodiment, cooling water supplied by the water-cooling system 80 shown in FIG. 20 absorbs heat, which is transferred from the electronic component 16 shown in FIG. 2 to the case body 21 of the case 3 via the heat conductive member 40. This causes the temperature of the case 3 to drop to increase a temperature difference between the case 3 and the electronic component 16, which accelerates heat transfer from the electronic component 16 to the case 3. Thus, the heat dissipation performance of the electronic component 16 the electronic control device 1M is further improved.

As described above, the electronic control device IN according to this embodiment further includes the water-cooling system 80 that supplies cooling water to the case 3 to cool the case 3. According to this configuration, heat transfer from the electronic component 16 to the case 3 is accelerated and therefore the heat dissipation performance of the electronic control device 1M is further improved.

### OTHER EMBODIMENTS

It should be noted that the present invention is not limited to the above embodiments but includes various modifications. For example, the above embodiments have been described in detail to give an understandable description of the present invention, and are not necessarily limited to an embodiment including all constituent elements described above. Some of constituent elements of one embodiment can be replaced with constituent elements of another embodiment, and a constituent element of another embodiment can be added to a constituent element of one embodiment. Some of constituent elements of this embodiment can be deleted or added to or replaced with different constituent elements.

For example, the above embodiments have been described as examples in which the electronic control device 1 is configured as an electronic control device that is incorporated in a vehicle to control or assist in driving the vehicle. However, the electronic control device as an electronic control device that performs high-speed communication may be incorporated in systems or equipment other than vehicles. For example, the electronic control device may be used as an electronic control device incorporated in an unmanned aerial vehicle (drone) or the like.

In the above embodiments, examples of the configuration in which the electronic component 16 capable of high-speed operation has the semiconductor package of the BGA structure have been described. However, the electronic component for high-speed processing may be configured to have a semiconductor package for surface mounting, such as a quad flat package (QFP) structure, a quad flat non-leaded package (QFN), or a small outline package (SOP) structure. In addition, the electronic component capable of high-speed operation may also be configured to have a semiconductor package for insertion mounting, such as a pin grid array (PGA) structure.

### REFERENCE SIGNS LIST

1, 1D, 1E, 1F, 1G, 1H, 1L, 1M, 1N electronic control device
2, 2A, 2B, 2C, 2D, 2E, 2F, 2G, 2H, 2J, 2K, 2L circuit board
3 case
11 printed wiring board (wiring board)
11a first surface
11b second surface
12, 12A, 12B, 12C high-speed signal line
13, 13E, 13F, 13G, 13H, 13J, 13K heat conductive path
16 electronic component
16a bottom surface
16b upper surface
16c outer peripheral surface (side surface)
32 IC chip (chip)
40, 40A, 40B, 40C, 40E, 40F heat conductive member (first heat conductive member)
50, 50E, 50F heat conductive member (second heat conductive member)
60 underfill (third heat conductive member)
70 cooling fan
80 water-cooling system

1. An electronic control device comprising:
a circuit board including a wiring board bearing a wiring pattern including a high-speed signal line, and an electronic component mounted on a first surface of both surfaces of the wiring board, the electronic component being electrically connected to the high-speed signal line;
a case housing the circuit board; and
a first heat conductive member in direct contact with the electronic component and with the case, wherein
the electronic component has a bottom surface facing the first surface of the wiring board, an upper surface located opposite to the bottom surface, and an outer peripheral surface connected to an outer edge of the bottom surface and to an outer edge of the upper surface, and wherein
the first heat conductive member is disposed in such a way as to extend from the upper surface of the electronic component to the case and to extend from the first surface of the wiring board to the case while being in contact with a part of the outer peripheral surface of the electronic component at a position at which the first heat conductive member avoids a space above the high-speed signal line.

2. The electronic control device according to claim 1, wherein
the electronic component is formed into a rectangular shape in a view from a side where the upper surface is located, and has four side surfaces as the outer peripheral surface, and wherein
the first heat conductive member is disposed in such a way as to extend from the first surface of the wiring board to the case while being in contact with a part of each side surface of the four side surfaces of the electronic component at a position at which the first heat conductive member avoids a space above the high-speed signal line.

3. The electronic control device according to claim 1, wherein
the electronic component has a chip serving as a built-in heat source, and wherein
the first heat conductive member is in contact with the upper surface of the electronic component in such a way as to include an entire area of an orthogonal projection of the chip onto the upper surface of the electronic component.

4. The electronic control device according to claim 1, wherein
the circuit board includes a heat conductive path provided on the wiring board, and wherein
the heat conductive path of the circuit board is disposed at a position at which the heat conductive path can be thermally connected to the first heat conductive member.

5. The electronic control device according to claim 4, further comprising a second heat conductive member in direct contact with a second surface of both surfaces of the wiring board, the second surface being located on the back of the first surface, and with the case, wherein
the second heat conductive member is thermally connected to the first heat conductive member via the heat conductive path of the circuit board.

6. The electronic control device according to claim 4, wherein
the electronic component is formed into a rectangular shape in a view from a side where the upper surface is located, and has four side surfaces as the outer peripheral surface, and wherein
the heat conductive path of the circuit board is disposed at a position at which the heat conductive path corresponds to a central part of at least one of the four side surfaces of the electronic component.

7. The electronic control device according to claim 4, wherein
the electronic component is formed into a rectangular shape in a view from a side where the upper surface is located, and has four side surfaces as the outer peripheral surface, wherein
the first heat conductive member is disposed in such a way as to be in contact with a part of each side surface of the four side surfaces of the electronic component at a position at which the first heat conductive member avoids a space above the high-speed signal line, and wherein
the heat conductive path of the circuit board is disposed in one-to-one correspondence to each side surface of the four side surfaces of the electronic component.

8. The electronic control device according to claim 4, wherein
the heat conductive path of the circuit board is disposed at a position closest to the outer peripheral surface of the electronic component.

9. The electronic control device according to claim 4, wherein
the electronic component has a heat source at a center of the electronic component, and wherein
a plurality of the heat conductive paths of the circuit board are spaced at positions equal in distance to the heat source of the electronic component.

10. The electronic control device according to claim 4, wherein
the heat conductive paths of the circuit board are a plurality of rows of heat conductive paths arranged in a direction along the outer peripheral surface of the electronic component.

11. The electronic control device according to claim 1, further comprising a third heat conductive member interposed between the first surface of the wiring board and the bottom surface of the electronic component.

12. The electronic control device according to claim 11, wherein
the third heat conductive member is an underfill that reinforces a solder joint on the bottom surface of the electronic component.

13. The electronic control device according to claim 1, further comprising a cooling fan that supplies cooling air to an outer surface of the case.

14. The electronic control device according to claim 1, further comprising a water-cooling system that supplies cooling water to the case to cool the case.
